(19) United States
(12) Patent Application Publication
(10) Pub. No.: US 2026/0253558 A1
(43) Pub. Date: Aug. 27, 2026

(54) DISPLAY DEVICE

(71) Applicant: LG Display Co., Ltd., Seoul (KR)

(72) Inventor: Jung Geun JO, Paju-si (KR)

(73) Assignee: LG Display Co., Ltd., Seoul (KR)

(21) Appl. No.: 19/438,164

(22) Filed: Dec. 31, 2025

(30) Foreign Application Priority Data
Dec. 31, 2024 (KR) 10-2024-0202934

(51) Int. Cl. G09G 3/3275; H10K 59/80

(52) U.S. Cl. CPC G09G 3/3275; H10K 59/8791; G09G 2320/045; G09G 2330/023; G09G 2360/16

(57) ABSTRACT

A display device can include a display panel having a first display area and a second display area, a data driver for applying a data signal to the display panel, and a timing controller for applying the data signal to the data driver. The display panel includes a first display area in which a plurality of first pixels are disposed, a second display area including a pixel area in which a plurality of second pixels are disposed and a plurality of light-transmission areas, and a luminance control member for controlling luminance of light emitted from the second display area.

### CROSS-REFERENCE TO RELATED APPLICATION

This application claims priority to and the benefit of Korean Patent Application No. 2024-0202934, filed in the Republic of Korea on Dec. 31, 2024, the disclosure of which is hereby expressly incorporated by reference in its entirety.

### BACKGROUND

### Field

Embodiments of the present disclosure relate to a display device.

### Discussion of the Related Art

Electroluminescence displays can be classified into inorganic electroluminescence displays and organic electroluminescence displays depending on the material of a light-emitting layer. Active matrix type organic electroluminescence displays include self-emissive organic light emitting diodes (hereinafter referred to as “OLEDs”), and have advantages such as fast response speeds, high luminous efficiency, high luminance, and wide viewing angles. In organic electroluminescence displays, OLEDs can be formed in respective pixels. The organic electroluminescence displays not only exhibit fast response speeds, high luminous efficiency, luminance, and wide viewing angles, but also can represent black gradation as perfect black, thereby providing excellent contrast ratios and color reproducibility.

Recently, mobile terminals have been improved in multimedia functions. For example, the mobile terminals can be equipped with built-in cameras, and the resolution of these cameras is trending toward a level comparable to that of the related art digital cameras. However, a front camera of the mobile terminal can restrict screen design, thereby making the screen design difficult.

Although screen designs including a notch or a punch hole have been adopted in mobile terminals in order to reduce the space occupied by the camera, the screen size can still be limited by the camera, so that it can be difficult to implement a full-screen display.

To achieve the full-screen display, methods have been proposed to provide an imaging area in which low-resolution pixels are disposed within the screen of a display panel, and to dispose a camera and/or various sensors in the imaging area.

The pixels disposed in the imaging area can have a limitation of rapid degradation because a high driving voltage can be applied to them in order to output at a level similar to that of the display area.

### SUMMARY OF THE DISCLOSURE

Embodiments of the present disclosure provide a display device capable of compensating for the luminance of an imaging area according to an input image and provide an improved display device which address the limitations associated with the related art.

The technical problems to be solved by the present disclosure are not limited to the above-mentioned problem, and other problems not mentioned can be clearly understood by those skilled in the art from the description of the invention described below.

A display device according to an embodiment can include a display panel including a first display area and a second display area; a data driver for applying a data signal to the display panel; and a timing controller for applying the data signal to the data driver, wherein the display panel includes a first display area in which a plurality of first pixels are disposed; a second display area including a pixel area in which a plurality of second pixels are disposed and a plurality of light-transmission areas; and a luminance control member for controlling luminance of light emitted from the second display area.

According to aspects of the present disclosure, the luminance control member can emit light to the second display area to control the luminance of light emitted from the second display area.

According to aspects of the present disclosure, the plurality of second pixels and the plurality of light-transmission areas of the second display area can be divided into a plurality of unit groups, and the luminance control member can include an auxiliary light source for controlling the luminance of light emitted from a luminance compensated area including the plurality of unit groups.

According to aspects of the present disclosure, the auxiliary light source can include a first auxiliary light source for emitting red light; a second auxiliary light source for emitting green light; and a third auxiliary light source for emitting blue light, wherein the first auxiliary light source can emit red light of minimum luminance within the luminance compensated area, the second auxiliary light source can emit green light of minimum luminance within the luminance compensated area, and the third auxiliary light source can emit blue light of minimum luminance within the luminance compensated area.

According to aspects of the present disclosure, the auxiliary light source can be overlapped with the pixel area and the light-transmission area.

According to aspects of the present disclosure, the auxiliary light source can be overlapped with the light-transmission area and may not be overlapped with the pixel area.

According to aspects of the present disclosure, the auxiliary light source can be disposed at a lower portion of a light-emitting layer of the second pixel.

According to aspects of the present disclosure, the luminance control member can include a diffusion plate disposed on the auxiliary light source.

According to aspects of the present disclosure, the luminance control member includes a light reflection filter disposed on the auxiliary light source, and the light reflection filter transmits or reflects external incident light so as to be incident on an imaging unit, and reflects or transmits light emitted from the luminance control member so as to be emitted to the outside.

According to aspects of the present disclosure, the timing controller can include a data receiver for receiving frame-by-frame image data; an image analyzer for analyzing the image data to extract minimum luminance of the second display area; a control signal generator for generating a control signal for controlling the luminance of the second pixel and the auxiliary light source according to the minimum luminance of the second display area; and a data transmitter for transmitting the control signal to the data driver and a luminance controller for controlling the luminance control member.

According to embodiments of the present disclosure, by compensating for luminance of the imaging area according to an input image, a driving voltage of pixels can be reduced, thereby enabling low-power driving and improving lifespan of the display device.

However, the effects of the present disclosure are not limited to the above-mentioned effects, and other effects not mentioned will be clearly understood by those skilled in the art from the description of the invention described below.

### BRIEF DESCRIPTION OF THE DRAWINGS

The above and other objects, features, and advantages of the present disclosure will become more apparent to those of ordinary skill in the art by describing example embodiments of the present disclosure thereof in detail with reference to the attached drawings, in which:

FIG. 1 is a conceptual diagram of a display device according to one embodiment of the present disclosure;

FIG. 2 is a cross-sectional view schematically showing a display device according to one embodiment of the present disclosure;

FIG. 3 is a diagram showing pixel arrangement of a first display area according to one embodiment of the present disclosure;

FIG. 4 is a diagram showing pixels and light-transmission areas of a second display area according to one embodiment of the present disclosure;

FIG. 5 is a diagram showing a state in which luminance of the second display area is controlled by a luminance control member according to one embodiment of the present disclosure;

FIG. 6 is a cross-sectional view schematically showing a display panel according to another embodiment of the present disclosure;

FIG. 7 is a diagram showing pixels and light-transmission areas of a second display area according to another embodiment of the present disclosure;

FIG. 8 is a cross-sectional view schematically showing a display panel according to still another embodiment of the present disclosure;

FIG. 9 is a block diagram showing a display device according to one embodiment of the present disclosure;

FIG. 10 is a block diagram showing a timing controller according to one embodiment of the present disclosure;

FIG. 11 is a flowchart showing a luminance control method of a second display area according to one embodiment of the present disclosure;

FIG. 12 is a diagram showing the luminance of the auxiliary light source and the second pixel in the case where an output coefficient of the luminance control member is 1.0 according to one embodiment of the present disclosure;

FIG. 13A is a diagram showing a state in which the second display area is visually recognized;

FIG. 13B is a diagram showing a state in which the second display area is not visually recognized as the luminance is controlled by the luminance control member according to one embodiment of the present disclosure;

FIG. 14 is a diagram showing the luminance of the auxiliary light source and the second pixel in the case where an output coefficient of the luminance control member is 0 according to one embodiment of the present disclosure;

FIG. 15 is a diagram showing the luminance of the auxiliary light source and the second pixel in the case where an output coefficient of the auxiliary light source is 1.0 according to another embodiment of the present disclosure;

FIG. 16 is a diagram showing the luminance of the auxiliary light source and the second pixel in the case where an output coefficient of the auxiliary light source is 0 according to another embodiment of the present disclosure;

FIG. 17 is a diagram showing a state in which the pixel luminance changes in a boundary area according to one embodiment of the present disclosure;

FIG. 18 is a diagram showing a state in which the luminance changes in a boundary area in the case where the output coefficient of the luminance control member is 1.0 according to one embodiment of the present disclosure;

FIG. 19 is a diagram showing a state in which the luminance changes in a boundary area in the case where the output coefficient of the luminance control member is 0 according to one embodiment of the present disclosure; and

FIG. 20 is a diagram showing a state in which the luminance changes in a boundary area in the case where the output coefficient of the luminance control member is 0.5 according to one embodiment of the present disclosure.

### DETAILED DESCRIPTION OF THE EMBODIMENTS

The advantages and features of the present disclosure, and methods of achieving them will be apparent from the embodiments of the present disclosure described in detail below in conjunction with the accompanying drawings. However, the present disclosure is not limited to the following embodiments, but can be implemented in various different forms; rather, the present embodiments of the present disclosure are provided to make the description of the present disclosure complete and to allow those skilled in the art to fully understand the scope of the present disclosure, and the present disclosure is defined only within the scope of the appended claims.

The shapes, sizes, proportions, angles, numbers and the like shown in the accompanying drawings for the purpose of illustrating the embodiments of the present disclosure are merely examples, and the present disclosure is not limited thereto. Identical reference numerals designate identical components throughout the description. Further, in describing the present disclosure, detailed descriptions of known related technologies can be omitted if it is considered to unnecessarily obscure the gist of the present disclosure.

The terms such as “including,” “having,” and “consisting of” used herein are generally intended to allow other components to be added unless the terms are used with the term “only.” When components are expressed in singular form, the plural form is also included unless specifically stated otherwise.

In the interpretation of components, they are construed to include margins of error, even if not explicitly stated.

When describing a positional relationship, for example, “on,” “above,” “below,” or “next to” describes the positional relationship of two parts, one or more other parts can be located between the two parts, unless “immediately” or “directly” is used. Further, the term “can” fully encompasses all the meanings and coverages of the term “may” and vice versa.

In description for the embodiments of the present disclosure, the first, second, etc. are used to describe various components, but these components are not limited by these terms. These terms are used only to distinguish one component from another. Therefore, the first component referred to herein can also be a second component within the technical idea of the present disclosure.

Identical reference numerals designate identical components throughout the description.

Each of the features of various embodiments of the present disclosure can be coupled or combined with one another in whole or in part, and can be technologically interconnected and operated in various ways, and each of the embodiments of the present disclosure can be carried out independently or in conjunction with one another.

Hereinafter, embodiments of the present disclosure will be described in detail with reference to the accompanying drawings. All the components of each display device/apparatus according to all embodiments of the present disclosure are operatively coupled and configured.

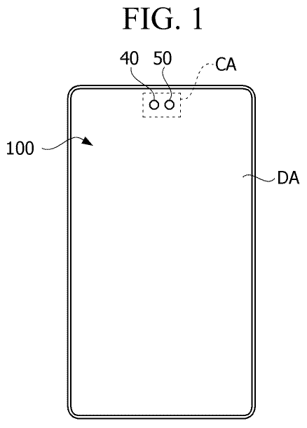

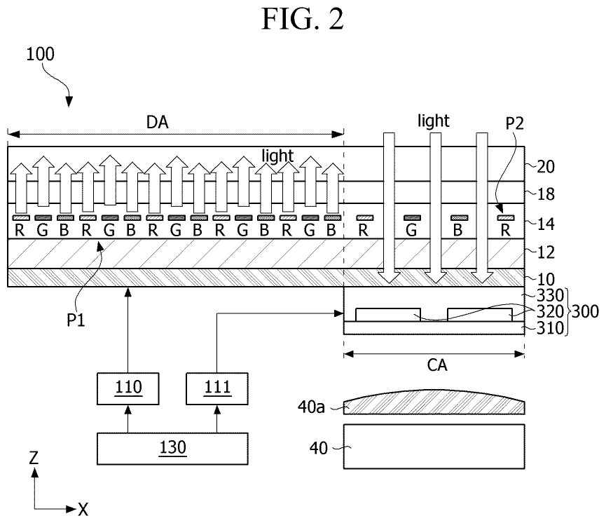

FIG. 1 is a conceptual diagram of a display device according to one embodiment of the present disclosure. FIG. 2 is a cross-sectional view schematically showing a display device according to one embodiment of the present disclosure.

Referring to FIG. 1, the display device can have a front surface of a display panel 100 configured as a display area. Accordingly, a full-screen display can be realized.

The display area can include a first display area DA and a second display area CA. The first display area DA and the second display area CA both output images, but their resolutions can be different. For example, the resolution of a plurality of second pixels disposed in the second display area CA can be lower than resolution (or density) of a plurality of first pixels disposed in the first display area DA. As the resolution (or density) of the plurality of second pixels disposed in the second display area CA decreases, a relatively larger amount of light can be introduced into sensors 40 and 50 disposed in the second display area CA.

However, the present disclosure is not necessarily limited thereto, and if the second display area CA has sufficient light transmittance or an appropriate compensation algorithm is implemented, the resolution of the first display area DA and the resolution of the second display area CA can be the same.

The second display area CA can be an area in which sensors 40 and 50 are disposed. Since the second display area CA is an area overlapped with various sensors, its area can be smaller than the first display area DA, which outputs most of the images. The second display area CA can be a sensing area in which various sensors collect information. The second display area CA is illustrated as being disposed at an upper portion of the display device, but is not limited thereto. Position and area of the second display area CA can be variously modified.

The sensors 40 and 50 can include at least one selected from an image sensor, a proximity sensor, an illuminance sensor, a gesture sensor, a motion sensor, a fingerprint recognition sensor, and a biometric sensor. For example, the first sensor 40 can be an imaging unit that captures images or moving images and the second sensor 50 can be an illuminance sensor or an infrared sensor, but is not limited thereto.

Referring to FIG. 2, the first display area DA and the second display area CA can include a pixel array in which pixels into which pixel data is written are disposed. The number of pixels per unit area (pixels per inch, hereinafter “PPI”) of the second display area CA can be lower than that of the first display area DA in order to secure light transmittance of the second display area CA.

The pixel array of the first display area DA can include a pixel area in which a plurality of pixels having high PPI are disposed. The pixel array in the second display area CA can include a pixel area in which a plurality of pixels are spaced apart by the light-transmission areas, so that they are disposed with relatively low PPI. In the second display area CA, external light can pass through the display panel 100 via the light-transmission areas having high light transmittance to be received by a sensor disposed below the display panel 100.

Since both the first display area DA and the second display area CA include pixels, an input image can be implemented on the first display area DA and the second display area CA. Accordingly, a full-screen display can be realized.

Each of the pixels in the first display area DA and the second display area CA can include sub-pixels of different colors to realize colors of an image. The sub-pixels can include red, green, and blue sub-pixels. The pixels can further include a white sub-pixel. Each of the sub-pixels can include a pixel circuit part and red, green, and blue light-emitting elements OLED.

The second display area CA can include pixels, and a lens 40a and an imaging unit 40 disposed below the screen of the display panel 100. The imaging unit 40 can be a camera including an image sensor. The pixels of the second display area CA can be written with pixel data of an input image in a display mode to display the input image.

The imaging unit 40 can capture an external image in a capturing mode to output photo or video image data. The lens 40a of the imaging unit 40 can face the second display area CA. The external light is incident on the lens 40a of the imaging unit 40 through the second display area CA, and the lens 40a can converge the light. The imaging unit 40 can be a camera module, but is not necessarily limited thereto, and can be various image acquisition devices capable of obtaining an image. An infrared sensor can also be disposed below the display panel screen.

In order to secure light transmittance, a picture quality compensation algorithm can be applied to compensate for luminance and color coordinates of the pixels in the second display area CA due to pixels removed from the second display area CA.

The display panel 100 can have a width in an X-axis direction, a length in a Y-axis direction, and a thickness in a Z-axis direction. The display panel 100 can include a circuit layer 12 disposed on a substrate 10 and a light-emitting element layer 14 disposed on the circuit layer 12. A polarizing plate 18 can be disposed on the light-emitting element layer 14, and a cover glass 20 can be disposed on the polarizing plate 18.

The circuit layer 12 can include pixel circuits connected to wirings such as data lines, gate lines, and power lines, and a gate driver connected to the gate lines.

The circuit layer 12 can include circuit elements such as transistors implemented as thin film transistors TFTs and capacitors. The wirings and circuit elements of the circuit layer 12 can be implemented as a plurality of insulating layers, two or more metal layers separated by the insulating layers, and an active layer including a semiconductor material.

The light-emitting element layer 14 can include light-emitting elements driven by the pixel circuits. The light-emitting elements can be implemented as OLEDs. The OLEDs can include an organic compound layer formed between an anode and a cathode.

The light-emitting element layer 14 can be disposed on the pixels that selectively transmit wavelengths of red, green, and blue, and can further include a color filter array.

The light-emitting element layer 14 can be covered with a protective film, and the protective film can be covered with an encapsulation layer. The protective layer and the encapsulation layer can have a structure in which organic films and inorganic films are alternately stacked. The inorganic film can block penetration of moisture or oxygen. The organic film can planarize a surface of the inorganic film. When the organic film and the inorganic film are stacked in multiple layers, penetration of moisture or oxygen affecting the light-emitting element layer 14 can be effectively blocked because a movement path of moisture or oxygen becomes longer compared with a single layer.

A polarizing plate 18 can be disposed on the encapsulation layer. The polarizing plate 18 can improve outdoor visibility of the display device. The polarizing plate 18 can reduce light reflected from the surface of the display panel 100 and block light reflected from the metal of the circuit layer 12 to improve brightness of the pixels. The polarizing plate 18 can be implemented as a polarizing plate in which a linear polarizing plate and a phase retardation film are bonded, or as a circular polarizing plate.

According to embodiments of the present disclosure, a luminance control member 300 can be disposed at a lower portion of the second display area CA. The luminance control member 300 can include a plurality of auxiliary light sources 320 disposed on a sub-substrate 310. The luminance control member 300 can be integrally manufactured with the display panel 100, but is not limited thereto. For example, the luminance control member 300 can be separately manufactured and attached to a lower portion of the display panel 100.

From the substrate 10 of the display panel 100, an area in which the luminance control member 300 is disposed can be removed. In this case, the output of light emitted from the luminance control member 300 can be improved.

The luminance control member 300 can output light to the second display area CA through the plurality of auxiliary light sources 320. Therefore, the luminance of light emitted from the second display area CA can be increased. Since the second pixels P2 in the second display area CA are relatively fewer in number, a higher driving voltage can be applied to obtain the same luminance as the first display area DA. Accordingly, the second pixel P2 can be easily deteriorated.

According to embodiments of the present disclosure, since the luminance control member 300 increases luminance of light emitted from the second display area CA, the driving voltage of the second pixel P2 can be lowered. Therefore, deterioration of the second pixel P2 can be prevented, thereby enabling a long lifetime.

According to embodiments of the present disclosure, a timing controller 130 of the display device can transmit image data of the first pixel P1 and the second pixel P2 to a data driver 110 that drives the display panel 100. In addition, the timing controller 130 can transmit a light emission control signal synchronized with the image data of the second pixel P2 to a luminance controller 111. The luminance controller 111 can apply a voltage to the auxiliary light sources 320 of the luminance control member 300.

The auxiliary light sources 320 of the luminance control member 300 can be manufactured with the same organic light-emitting elements as the first pixels P1, but the embodiments of the present disclosure are not limited thereto. For example, the auxiliary light sources 320 of the luminance control member 300 can be a liquid crystal display device or can be micro-LEDs.

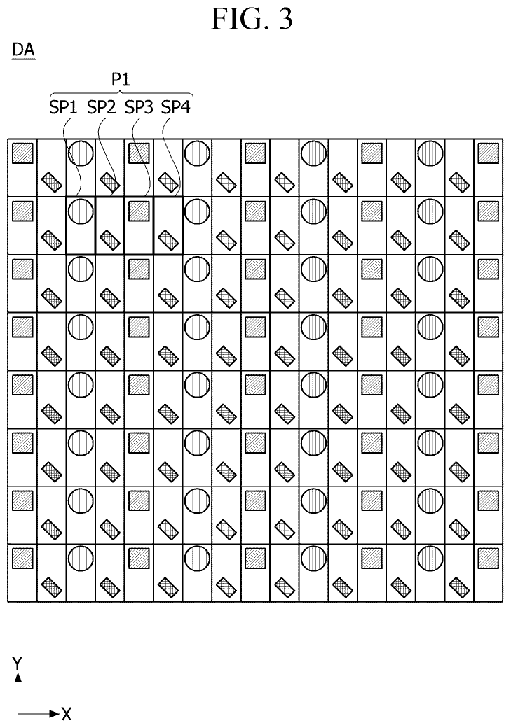

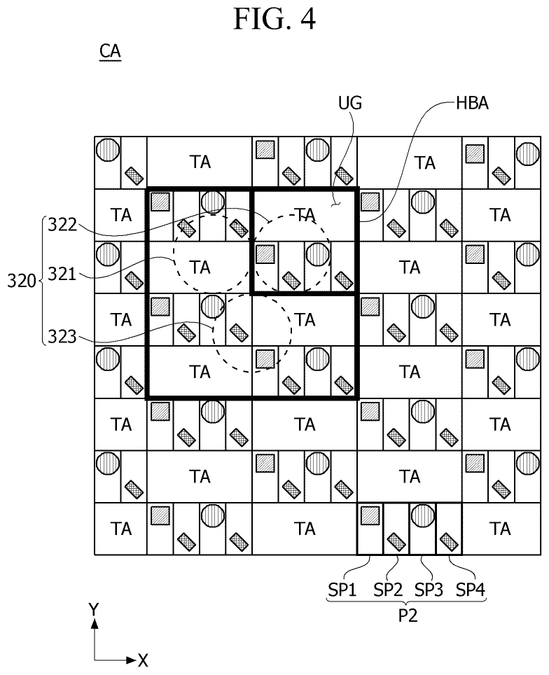

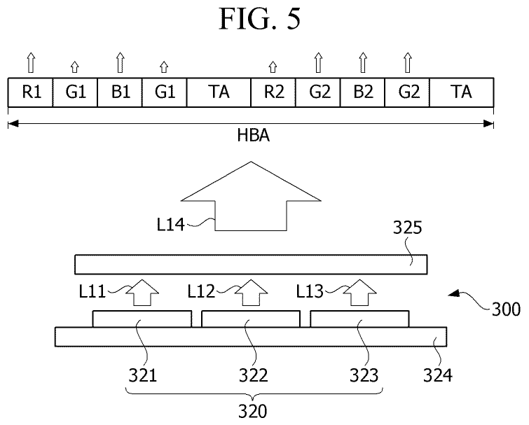

FIG. 3 is a diagram showing pixel arrangement of a first display area according to one embodiment of the present disclosure. FIG. 4 is a diagram showing pixels and light-transmission areas of a second display area according to one embodiment of the present disclosure. FIG. 5 is a diagram showing a state in which luminance of the second display area is controlled by a luminance control member according to one embodiment of the present disclosure.

Referring to FIG. 3, the first display area DA can include a plurality of first pixels P1 arranged in a matrix form. The plurality of first pixels P1 can include a first sub-pixel SP1, a second sub-pixel SP2, a third sub-pixel SP3 and a fourth sub-pixel SP4. For example, the first sub-pixel SP1 can be a blue pixel, the second sub-pixel SP2 and the fourth sub-pixel SP4 can be green pixels, and the third sub-pixel SP3 can be a red pixel.

Referring to FIG. 4, the second display area CA can include a plurality of second pixels P2 and a plurality of light-transmission areas TA. The plurality of light-transmission areas TA can be disposed between the plurality of second pixels P2. Specifically, the light-transmission areas TA can be alternately disposed with the second pixel P2 in a first direction and a second direction, respectively. The external light can be received by the imaging unit through the light-transmission areas TA. As the area of the light-transmission areas TA increases, the resolution of the second display area CA can be lower than that of the first display area DA.

The light-transmission areas TA can include transparent media having high light transmittance without metal so that light can be incident as much as possible. The light-transmission areas TA can be formed of transparent insulating materials without including metal wirings or pixels. The light transmittance of the second display area CA can increase as the light-transmission areas TA become larger.

The plurality of second pixels P2 can include a first sub-pixel SP1, a second sub-pixel SP2, a third sub-pixel SP3, and a fourth sub-pixel SP4. For example, the first sub-pixel SP1 can be a blue pixel, the second sub-pixel SP2 and the fourth sub-pixel SP4 can be green pixels, and the third sub-pixel SP3 can be a red pixel.

The shape of the light-transmission area TA is exemplified as a rectangle, but is not limited thereto. For example, the light-transmission area TA can be designed in various shapes such as a circle, an ellipse, or a polygon.

All metal electrode materials in the light-transmission area TA can be removed. Accordingly, wirings of the pixels can be disposed outside the light-transmission area TA. Therefore, light can be effectively incident through the light-transmission area TA. However, embodiments of the present disclosure are not necessarily limited thereto, and the auxiliary light source 320 or metal electrode materials can be present within some area within the light-transmission area TA.

According to embodiments of the present disclosure, the second display area CA can be divided into a plurality of unit groups UG. The unit group UG can include at least one second pixel P2 and at least one light-transmission area TA. For example, the unit group UG can include one pixel and three light-transmission areas TA.

The auxiliary light sources 320 can be disposed for each luminance compensated area HBA, and the luminance compensated area HBA can be composed of a plurality of unit groups UG. The auxiliary light sources 320 can control luminance of light emitted from a plurality of luminance compensated areas HBA.

The plurality of auxiliary light sources 320 can include a first auxiliary light source 321 that emits red light, a second auxiliary light source 322 that emits green light, and a third auxiliary light source 323 that emits blue light. The plurality of auxiliary light sources 320 can emit light of the minimum luminance within the luminance compensated area HBA.

For example, when one of the pixels in the luminance compensated area HBA outputs light of the lowest luminance at a 31-gradation level, the auxiliary light sources 320 can also output light of the 31-gradation level. For example, when one of the plurality of sub-pixels in the luminance compensated area HBA is turned off to output light of the lowest 0-gradation level (black data), the auxiliary light sources 320 can also be turned off.

Referring to FIG. 5, the plurality of auxiliary light sources 320 can be disposed at a lower portion of a second-first pixel and a second-second pixel. The second-first pixel can include a first blue pixel B1, a first green pixel G1, and a first red pixel R1, and the second-second pixel can include a second blue pixel B2, a second green pixel G2, and a second red pixel R2.

The first auxiliary light source 321 can output red light of the minimum luminance in the luminance compensated area HBA. For example, luminance of the second red pixel R2 within the luminance compensated area HBA can be lower than that of the first red pixel R1. For example, among the red pixels in the luminance compensated area HBA, the luminance of the second red pixel R2 can be the lowest. Therefore, the first auxiliary light source 321 can emit red light L11 having the same luminance as the second red pixel R2 which outputs a minimum luminance. In the case where the first auxiliary light source 321 emits red light having the same luminance as the first red pixel R1, the luminance of red light to be emitted from the second red pixel R2 can become higher, and a desired image may not be implemented.

Likewise, the second auxiliary light source 322 can emit green light L12 of the lowest luminance in the luminance compensated area HBA. In addition, the third auxiliary light source 323 can emit blue light L13 of the lowest luminance in the luminance compensated area HBA. Mixed light L14, in which the red light L11 of the first auxiliary light source 321, the green light L12 of the second auxiliary light source 322, and the blue light L13 of the third auxiliary light source 323 are mixed, can pass through the diffusion plate 325 and be incident on the luminance compensated area HBA.

With this configuration, since the auxiliary light sources 320 emit light of minimum luminance for each unit group UG, the pixels of the unit group UG can be controlled to have a lower voltage by the compensated luminance, thereby preventing excessively high data voltages from being applied.

A diffusion plate 325 can be disposed on an upper portion of the first to third auxiliary light sources 321, 322, and 323. Accordingly, the light emitted from the first to third auxiliary light sources 321, 322, and 323 can be mixed and incident on the second pixel P2 and the light-transmission areas TA. The diffusion plate 325 can broaden the luminance compensated area HBA.

The size of the luminance compensated area HBA is not particularly limited. In the case where the size of the luminance compensated area HBA is made small, auxiliary light can be provided for each unit group UG so that the data voltage applied to the second pixel P2 can be optimized. However, in such a case, a relatively large number of auxiliary light sources 320 must be disposed. Therefore, the auxiliary light sources 320 can be disposed by selecting an appropriate size of the unit group UG. For example, the luminance compensated area HBA can be the entire area of the second display area CA. For example, the luminance compensated area HBA can be divided into an area in which an imaging area is disposed and an area where an infrared sensor is disposed.

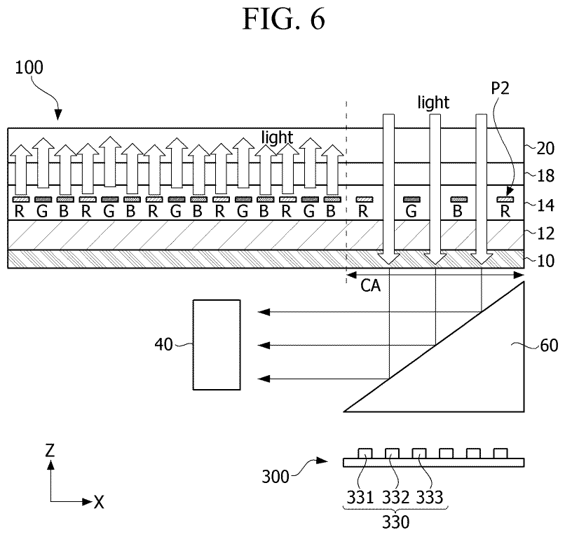

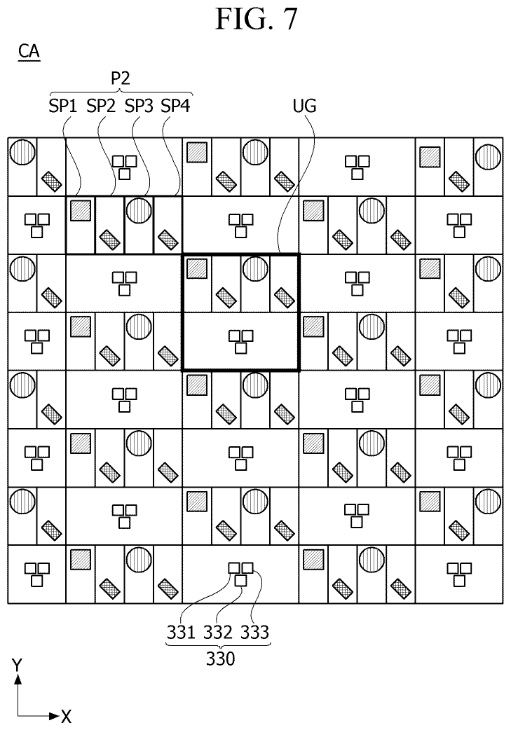

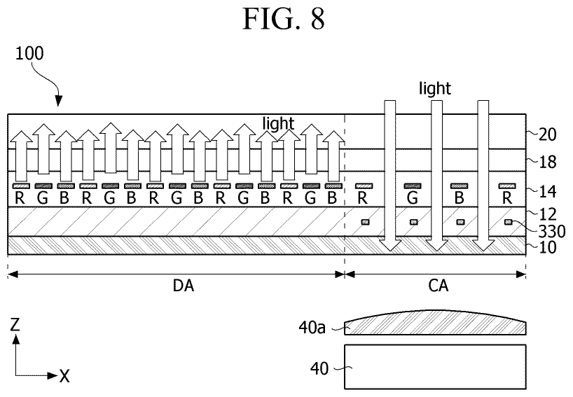

FIG. 6 is a cross-sectional view schematically showing a display panel according to another embodiment of the present disclosure. FIG. 7 is a diagram showing pixels and light-transmission areas of a second display area according to another embodiment of the present disclosure. FIG. 8 is a cross-sectional view schematically showing a display panel according to still another embodiment of the present disclosure.

Referring to FIGS. 6 and 7, the luminance control member 300 can include a plurality of micro light-emitting elements. The plurality of micro light-emitting elements 330 can include a plurality of first micro light-emitting elements 331 that emit blue light, a plurality of second micro light-emitting elements 332 that emit green light, and a plurality of third micro light-emitting elements 333 that emit red light. Since the sizes of the micro light-emitting elements are smaller than those of the second pixel P2, deterioration of light transmittance can be minimized.

A light reflection filter 60 can be disposed between the substrate 10 of the display panel and the luminance control member 300. The light reflection filter 60 can reflect (or transmit) light incident to the second display area CA to the imaging unit 40, and can transmit (or reflect) light emitted from the luminance control member 300 to the second display area CA. However, the embodiments of the present disclosure are not limited thereto, and the light reflection filter 60 can be omitted.

Referring to FIG. 7, the second display area CA can be divided into a plurality of unit groups UG. The unit group UG can include at least one second pixel P2 and at least one light-transmission area TA. For example, the unit group UG can include one pixel and one light-transmission area TA. For example, the unit group UG can include one pixel and three light-transmission areas TA.

A plurality of micro light-emitting elements 330 can be disposed in each unit group UG. According to embodiments of the present disclosure, the size of the luminance compensated area HBA can be the same as the size of the unit group UG. The plurality of micro light-emitting elements 330 can individually control luminance of light emitted from the plurality of unit groups UG. The plurality of micro light-emitting elements 330 can emit light of minimum luminance within the unit groups UG. The plurality of micro light-emitting elements can constitute the auxiliary light source.

For example, the first micro light-emitting element 331 can emit blue light of the minimum luminance within the unit group UG. The second micro light-emitting element 332 can emit green light of the minimum luminance within the unit group UG. The third micro light-emitting element 333 can emit red light of the minimum luminance within the unit group UG.

According to embodiments of the present disclosure, since one second pixel P2 is disposed in one unit group UG, the luminance of the first micro light-emitting element 331 can be the same as that of the first sub-pixel SP1. In addition, the luminance of the second micro light-emitting element 332 can be the same as that of the second sub-pixel SP2 and the fourth sub-pixel SP4, and the luminance of the third micro light-emitting element 333 can be the same as that of the third sub-pixel SP3.

Referring to FIG. 8, the luminance control member 300 can be disposed in an inner portion of the display panel. The luminance control member 300 can be disposed at a lower portion of the second pixel P2. With this configuration, the display panel 100 and the luminance control member 300 can be manufactured together. For example, after components of the luminance control member 300 are first manufactured on the substrate 10, the second pixel P2 can be manufactured thereon. The auxiliary light sources of the luminance control member 300 can be the same organic light-emitting elements as the second pixel P2 or can be micro light-emitting elements 330.

However, the embodiments of the present disclosure are not limited thereto. For example, the auxiliary light sources of the luminance control member 300 can be disposed between the second pixels P2. If the auxiliary light sources of the luminance control member 300 and the second pixel P2 are disposed on the same layer, the luminance of light emitted from the auxiliary light sources can be improved.

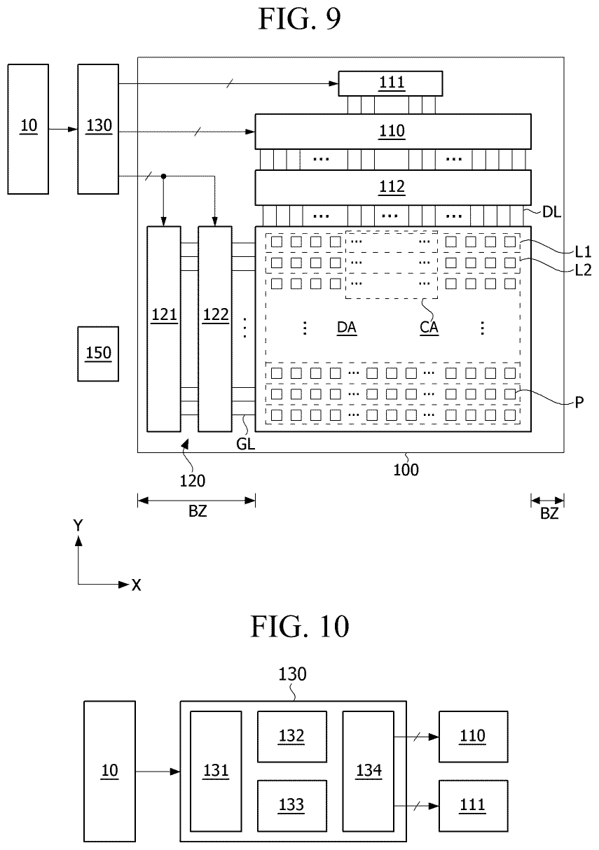

FIG. 9 is a block diagram showing a display device according to one embodiment of the present disclosure;

Referring to FIG. 9, the display device according to one embodiment of the present disclosure can include a display panel 100, display panel drivers 110, 111, and 120 for writing pixel data of an input image into the pixels P of the display panel 100, a timing controller 130 for controlling the display panel drivers 110, 111, and 120, and a power supply 150 for generating power required for driving the display panel 100.

The display panel 100 can include a pixel array for displaying an input image on a screen. As described above, the pixel array can be divided into a first display area DA and a second display area CA having lower resolution or PPI compared with the first display area DA. The first display area DA can include pixels P with high PPI, and since it is larger than the second display area CA, most image information is displayed in the first display area DA. A sensor module overlapped with the second display area CA can be disposed below the display panel 100.

Touch sensors can be disposed on the screen of the display panel 100. The touch sensors can be implemented as on-cell type or add-on type touch sensors disposed on the screen of the display panel, or as in-cell type touch sensors embedded in the pixel array.

The display panel 100 can be implemented as a flexible display panel in which pixels P are disposed on a flexible substrate such as a plastic substrate or a metal substrate. A flexible display can vary in screen size and shape by winding, folding, or bending a flexible display panel. The flexible display can include a slidable display, a rollable display, a bendable display, a foldable display, and the like.

The display panel drivers 110, 111, and 120 can reproduce an input image on the screen of the display panel 100 by writing pixel data of the input image into the sub-pixels. The display panel drivers 110, 111, and 120 can include a data driver 110, a luminance controller 111, and a gate driver 120. The display panel drivers 110, 111, and 120 can further include a demultiplexer 112 disposed between the data driver 110 and the data lines DL.

The data driver 110 can sample pixel data to be written into the pixels of the first display area DA from pixel data received from the timing controller 130. The data driver 110 can convert the pixel data to be written into the pixels of the first display area DA into gamma-compensated voltages and output data voltages Vdata. The data voltage Vdata output from the channels of the data driver 110 can be applied to the data lines DL connected to the pixels of the first display area DA through the demultiplexer 112, or can be directly applied to those data lines DL.

The demultiplexer 112 can distribute the data voltages Vdata output through the channels of the data drivers (110 and 111) to a plurality of data lines DL in a time-division manner. By the demultiplexer 112, the number of channels of the data driver 110 can be reduced. The demultiplexer 112 can be omitted.

The gate driver 120 can be implemented as a gate in panel (GIP) circuit formed directly on the bezel area BZ of the display panel 100 together with a TFT array of the pixel array. The gate driver 120 can output a gate signal to the gate lines GL connected to the pixels of the first display area DA under the control of the timing controller 130. The gate driver 120 can sequentially supply gate signals to the gate lines GL connected to the pixels of the first display area DA by shifting the gate signals using a shift register. The voltage of the gate signal can swing between a gate-off voltage VGH and a gate-on voltage VGL.

The gate signals applied to the pixels of the first display area DA can include pulses of a scan signal (hereinafter referred to as a scan pulse) and pulses of a light emission control signal (hereinafter referred to as an EM pulse). The gate lines GL connected to the pixels of the first display area DA can include scan lines to which scan pulses are applied, and EM lines to which EM pulses are applied.

The gate driver 120 can include a first-first gate driver 121 and a first-second gate driver 122. The first-first gate driver 121 can output the scan pulse and can sequentially supply the scan pulse to the scan lines connected to the pixels of the first display area DA and the second display area CA by shifting the scan pulse according to a shift clock. The first-second gate driver 122 can output the EM pulse and can sequentially supply the EM pulse to the EM lines connected to the pixels of the first display area DA by shifting the EM pulse according to a shift clock.

The timing controller 130 can receive pixel data of an input image and timing signals synchronized with the pixel data from a host system. The timing signals can include a vertical sync signal Vsync, a horizontal sync signal Hsync, a clock CLK, and a data enable signal DE. One period of the vertical sync signal Vsync can be one frame period. One period of the horizontal sync signal Hsync and the data enable signal DE can be one horizontal period 1H. A pulse of the data enable signal DE can be synchronized with one-line data to be written into the pixels P of one pixel line. Since the frame period and the horizontal period can be identified by counting the data enable signal DE, the vertical sync signal Vsync and the horizontal sync signal Hsync can be omitted.

The timing controller 130 can transmit pixel data of an input image to the first and second data drivers 110 and 111, and can control the operation timing of the display panel drivers 110, 111, and 120 to synchronize the data driver 110, the demultiplexer 112, and the gate driver 120.

The timing controller 130 can multiply an input frame frequency by i (where i is a natural number) and can control the operation timing of the display panel drivers 110, 111, and 120 at a frame frequency of the input frame frequency×i Hz. The input frame frequency can be 60 Hz in a national television standards committee (NTSC) system and 50 Hz in a phase-alternating line (PAL) system. The timing controller 130 can reduce the frame frequency to a frequency between 1 Hz and 30 Hz in order to lower a refresh rate of the pixels P in a low-speed driving mode.

The timing controller 130 can generate, based on the timing signals Vsync, Hsync, and DE received from the host system, a data timing control signal for controlling operation timing of the data driver 110, a switch control signal for controlling operation timing of the demultiplexer 112, and a gate timing control signal for controlling operation timing of the gate driver 120.

The gate timing control signal can include a start pulse, a shift clock, a reset signal, an initialization signal, and the like. A voltage level of the gate timing control signal output from the timing controller 130 can be converted into a gate-off voltage VGH/VEH and a gate-on voltage VGL/VEL through a level shifter omitted in the drawing to be supplied to the gate driver 120. The level shifter can convert a low-level voltage of the gate timing control signal into the gate-on voltage VGL, and can convert a high-level voltage of the gate timing control signal into the gate-off voltage VGH.

The power supply 150 can include a charge pump, a regulator, a buck converter, a boost converter, a programmable gamma IC (P-GMA IC), and the like. The power supply 150 can adjust a direct current input voltage from a host system and generate power required for driving the display panel drivers 110, 111, and 120 and the display panel 100. The power supply 150 can output direct current voltages such as a gamma reference voltage, a gate-off voltage VGH/VEH, a gate-on voltage VGL/VEL, a pixel driving voltage ELVDD, a low-potential power supply voltage ELVSS, an initialization voltage Vini, and a reference voltage Vref. The programmable gamma IC can vary the gamma reference voltage according to register settings. The gamma reference voltage can be supplied to the data driver 110. The gate-off voltage VGH/VEH and the gate-on voltage VGL/VEL can be supplied to the level shifter and the gate driver 120. The pixel driving voltage ELVDD, the low-potential power supply voltage ELVSS, the initialization voltage Vini, and the reference voltage Vref can be commonly supplied to the pixel circuits through power supply lines. The pixel driving voltage ELVDD can be set to a voltage higher than the low-potential power supply voltage ELVSS, the initialization voltage Vini, and the reference voltage Vref.

The host system can be a main circuit board of a television (TV) system, a set-top box, a navigation system, a personal computer (PC), a vehicle system, a home theater system, a mobile device, or a wearable device.

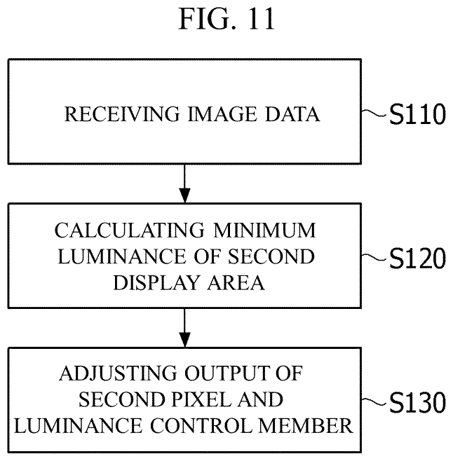

FIG. 10 is a block diagram showing a timing controller according to one embodiment of the present disclosure. FIG. 11 is a flowchart showing a luminance control method of a second display area according to one embodiment of the present disclosure.

Referring to FIGS. 10 and 11, the luminance control method of the second display area CA can include receiving image data in step S110, calculating the minimum luminance of the second display area CA in step S120, and adjusting outputs of the second pixel P2 and the luminance control member 300 based on the minimum luminance in step S130.

In step S110 of receiving image data, the timing controller 130 can receive frame-by-frame image data from a host. The timing controller 130 can receive and store the frame-by-frame image data and then can transmit the image data to the data driver 110 in units of one horizontal period.

The timing controller 130 can include a data receiver 131 that receives the frame-by-frame image data, an image analyzer 132 that analyzes the image data to extract the minimum luminance of the second display area CA, a control signal generator 133 that generates a control signal for controlling luminance of the second pixel P2 and the auxiliary light source 320 according to the minimum luminance of the second display area CA, and a data transmitter 134 that transmits the control signal to the data driver 110 and the luminance controller 111.

In step S120 of calculating the minimum luminance of the second display area CA, the image analyzer 132 can analyze the received image data. The image analyzer 132 can analyze the image data of each unit group UG of the second display area CA and can extract the minimum luminance of each unit group UG. The method of extracting the minimum luminance is not particularly limited. Since the image data indicates luminance information according to pixel positions, the pixel having the minimum luminance can be extracted from the image data corresponding to the second display area CA.

In step S130 of adjusting outputs of the second pixel P2 and the luminance control member 300, the control signal generator 133 can set a data voltage of the auxiliary light source 320 so that the auxiliary light source 320 outputs the minimum luminance according to the minimum luminance information extracted by the image analyzer 132.

The control signal generator 133 can adjust the luminance of the second pixel P2 according to an image to be output from the second display area CA. For example, the control signal generator 133 can generate a control signal so that the minimum luminance of an image to be displayed in the second display area CA is output from the auxiliary light source 320, and can modulate data so that the second pixel P2 have luminance capable of displaying the corresponding image.

The data transmitter 134 can transmit image data information of the second pixel P2 generated by the control signal generator 133 to the first data driver 110, and can transmit an output control signal of the auxiliary light source 320 to the luminance controller 111. The first data driver 110 and the luminance controller 111 can be implemented as a single integrated circuit.

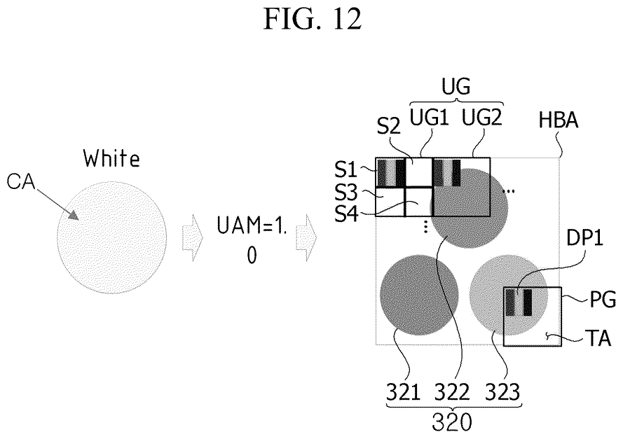

FIG. 12 is a diagram showing the luminance of the auxiliary light source and the second pixel in the case where an output coefficient of the luminance control member is 1.0 according to one embodiment of the present disclosure.

Referring to FIG. 12, the luminance control member 300 can be adjusted so that the output coefficient UAM is from 0 to 1.0. In the case where the output coefficient UAM is 0, a voltage is not applied to the auxiliary light source 320 so that it can be turned off; and in the case where the output coefficient UAM is 1.0, a maximum voltage is applied to the auxiliary light source 320 so that it can be turned on at 100% luminance. In the case where the output coefficient UAM is 0.5, the auxiliary light source 320 can be turned on at 50% of maximum output. The output coefficient can be determined by the minimum luminance of the unit group UG.

The unit group UG can include one second pixel P2, and the remaining areas can be light-transmission areas TA. Therefore, when the unit group UG is divided into four portions, a first unit pixel DP1 can be disposed in a first area S1, and second to fourth areas S2, S3, and S4 can be the light-transmission areas TA. However, embodiments of the present disclosure are not limited thereto, and area of the second pixel P2 and the light-transmission areas TA within the unit group UG can be variously changed. The auxiliary light source 320 can output light having the minimum luminance of the luminance compensated area HBA.

In the case where a white image is implemented in the second display area CA, the minimum luminance of the unit group UG can be white gradation. Accordingly, the output coefficient of the luminance control member 300 can be controlled to 1.0, and white light can be output from the auxiliary light source 320 through the light-transmission area TA.

In the first unit pixel DP1, 100% output can be applied so that white light is output in the first area S1 of the unit group UG. Therefore, in the second to fourth areas S2, S3, and S4, the white light can be emitted by the auxiliary light source 320, and in the first area S1, white the white light can be emitted by the first unit pixel DP1, so that the unit group UG can emit the white light as a whole.

If the auxiliary light source 320 is not provided, the first unit pixel DP1 should be responsible for the luminance of white light for the entire area of the unit group UG, and therefore the driving voltage should be output at 400%. The driving voltage of 400% can be understood to mean four times the driving voltage applied to the first unit pixel DP1 to implement the maximum luminance in the first area.

Therefore, the data voltage in the first unit pixel DP1 can become excessively high, making it susceptible to degradation. However, according to the embodiment, since the minimum luminance is supplemented by the auxiliary light source 320, the data voltage applied to the first unit pixel DP1 can be reduced.

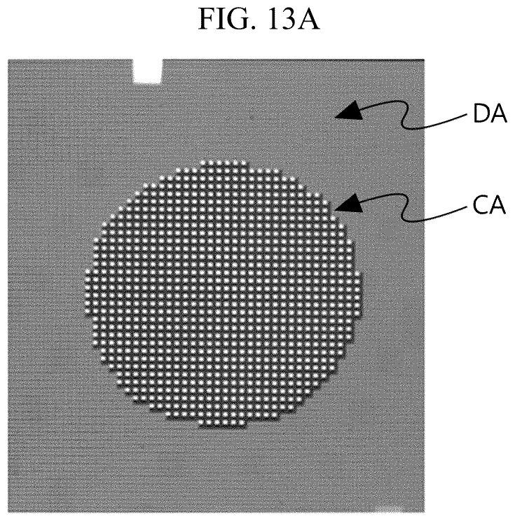

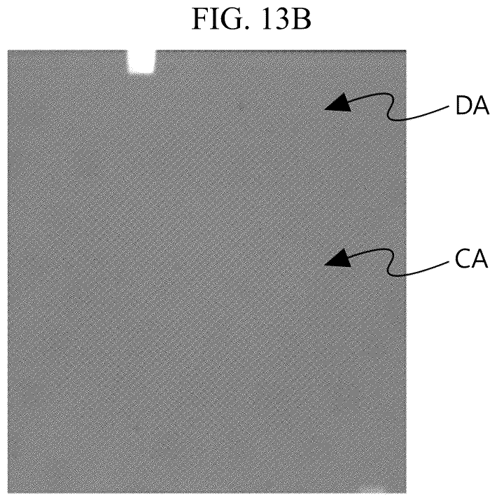

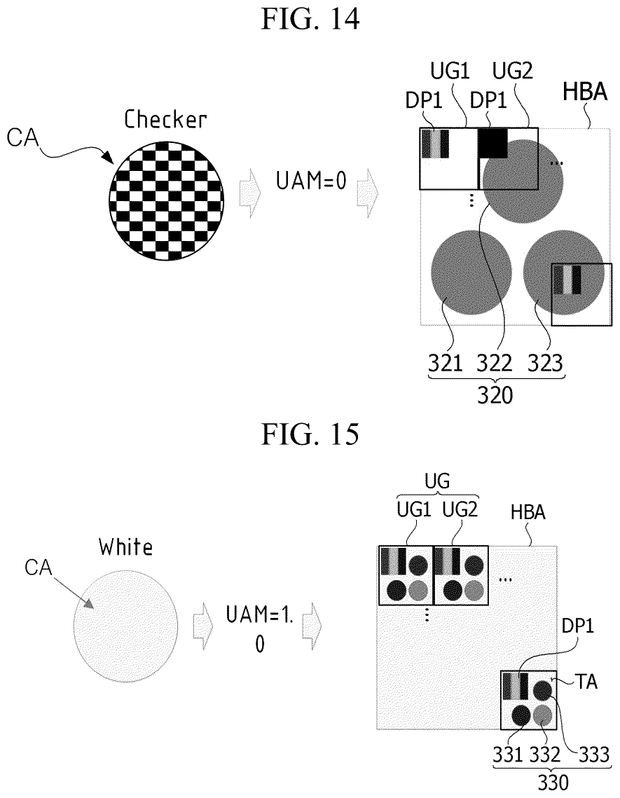

FIG. 13A is a diagram showing a state in which the second display area is visually recognized. FIG. 13B is a diagram showing a state in which the second display area is not visually recognized as the luminance is controlled by the luminance control member according to one embodiment of the present disclosure. FIG. 14 is a diagram showing the luminance of the auxiliary light source and the second pixel in the case where an output coefficient of the luminance control member is 0 according to one embodiment of the present disclosure.

Referring to FIG. 13A, in the case where the auxiliary light source 320 is not provided, the second display area CA, in which pixels are relatively few, has a problem in that the boundary with the first display area DA is visually recognized. However, referring to FIG. 13B, in the case where the auxiliary light source 320 is provided, since the minimum luminance is maintained in the second display area CA, the boundary with the first display area DA is not easily visually recognized.

Referring to FIG. 14, in the case where the image of the second display area CA is a checkered image, a white image and a black image can be alternately output. In this case, since the minimum luminance is black, the output coefficient of the auxiliary light source 320 can be zero. Therefore, the auxiliary light source 320 is turned off, and the first unit pixel DP1 is turned on to output the checkered image.

In the first unit group UG1 in which a white image is output, since the first unit pixel DP1 has to implement the white image of the entire first unit group UG1, the driving voltage can be output at 400%. The driving voltage of 400% can mean four times the driving voltage of 100% applied to the first unit pixel DP1 to implement the maximum luminance in the first unit group UG1.

In the second unit group UG2 in which a black image is output, the first unit pixel DP1 can be turned off. Therefore, in the second unit group UG2, since both the first unit pixel DP1 and the auxiliary light source 320 are turned off, a black image can be output.

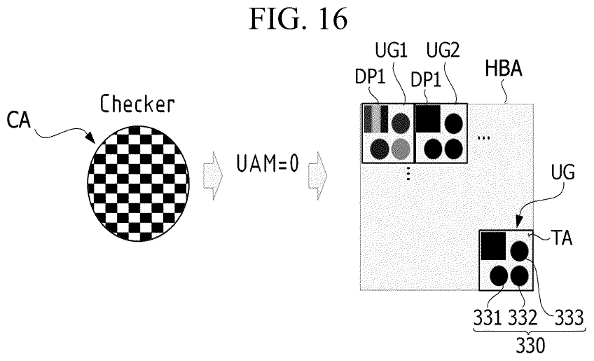

FIG. 15 is a diagram showing the luminance of the auxiliary light source and the pixel in the case where the output coefficient of the auxiliary light source is 1.0 according to another embodiment of the present disclosure. FIG. 16 is a diagram showing the luminance of the auxiliary light source and the pixel in the case where the output coefficient of the auxiliary light source is 0 according to another embodiment of the present disclosure.

Referring to FIG. 15, the unit group UG can include one first unit pixel DP1, and the remaining areas can be light-transmission areas TA. The auxiliary light source 330 can be disposed in the light-transmission area TA. The auxiliary light source (330) can be a micro light-emitting element, but the present embodiments of the present disclosure are not limited thereto.

In the first unit pixel DP1, 100% output can be applied so that white light is output in the first area of the unit group UG. Therefore, in the light-transmission areas TA, the white light can be emitted by the auxiliary light source 330, and in the first area, white the white light can be emitted by the first unit pixel DP1, so that the unit group UG can emit the white light as a whole.

If the auxiliary light source 330 is not provided, the first unit pixel DP1 should output white light for the entire area of the unit group UG, and therefore the driving voltage should be output at 400%. Therefore, the data voltage in the first unit pixel DP1 can become excessively high, making it susceptible to degradation. However, according to the embodiment, since the minimum luminance is maintained by the auxiliary light source 320, the data voltage applied to the first unit pixel DP1 can be reduced.

Referring to FIG. 16, in the case where the image of the second display area CA is a checkered image, a white image and a black image can be alternately output.

In the first unit group UG1 in which a white image is output, the auxiliary light source 330 can be output with the output coefficient of 1.0, and the first unit pixel DP1 can be output with the data voltage of 100% to implement the white image.

In the second unit group UG2 in which a black image is output, the first unit pixel DP1 can be turned off. Therefore, in the second unit group UG2, since both the first unit pixel DP1 and the auxiliary light source 330 are turned off, a black image can be output.

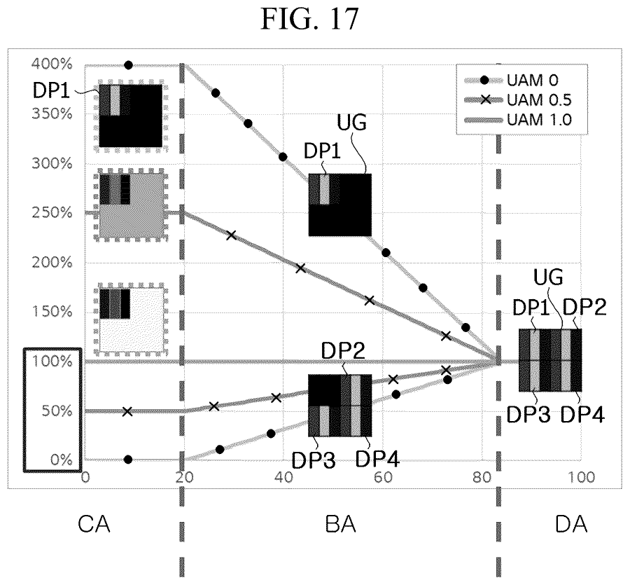

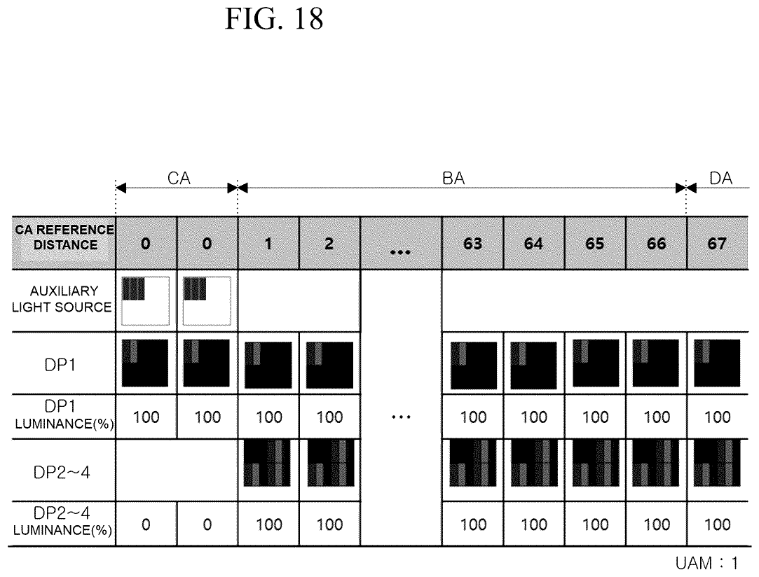

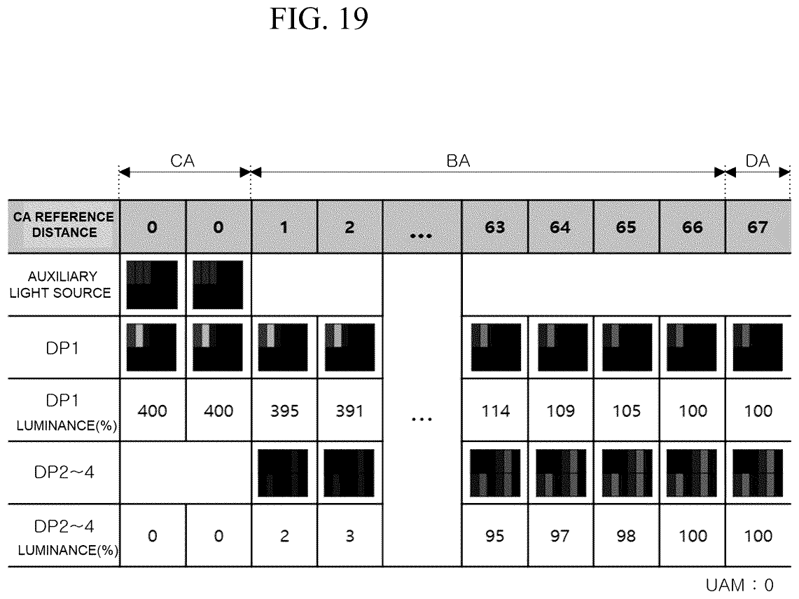

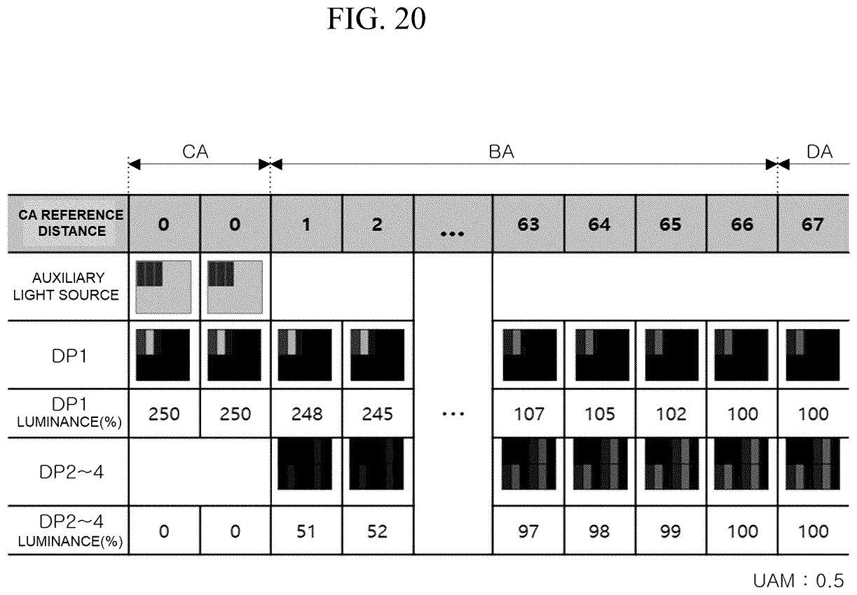

FIG. 17 is a diagram showing a state in which the pixel luminance changes in a boundary area according to one embodiment of the present disclosure. FIG. 18 is a diagram showing a state in which the luminance changes in a boundary area in the case where the output coefficient of the luminance control member is 1.0 according to one embodiment of the present disclosure. FIG. 19 is a diagram showing a state in which the luminance changes in a boundary area in the case where the output coefficient of the luminance control member is 0 according to one embodiment of the present disclosure. FIG. 20 is a diagram showing a state in which the luminance changes in a boundary area in the case where the output coefficient of the luminance control member is 0.5 according to one embodiment of the present disclosure.

Referring to FIG. 17, a boundary area BA can be disposed between the first display area DA and the second display area CA. The boundary area BA can prevent the second display area CA from being visually recognized due to a luminance difference between the first display area DA and the second display area CA.

The second display area CA can have one pixel disposed in the unit group UG, while the first display area DA and the boundary area BA can have four pixels disposed in the unit group UG. The unit group UG can include at least one of a first unit pixel DP1 disposed in a first area, a second unit pixel disposed in a second area, a third unit pixel disposed in a third area, and a fourth unit pixel disposed in a fourth area. The pixels of the first display area DA and the boundary area BA can include all of the first to fourth unit pixels DP1, DP2, DP3, and DP4, but the pixels of the second display area CA can include only the first unit pixel DP1. In FIG. 17, the X-axis can represent the relative distance from the center of the second display area, and the Y-axis can represent relative luminance.

Referring to FIG. 18, in the second display area CA, white images can be implemented by outputting the auxiliary light source 320 at 100% luminance and by outputting the first unit pixel DP1 at 100% luminance. The boundary area BA and the first display area DA can implement white images by outputting all of the first to fourth unit pixels DP1 to DP4 at 100% luminance. In this case, since white images are output in the unit groups UG of the second display area CA, the boundary area BA, and the first display area DA, there can be no luminance difference, so that the second display area CA may not be visually recognized.

Referring to FIG. 19, in the second display area CA, white images can be implemented by turning off the auxiliary light source 320 and by outputting the first unit pixel DP1 at 400% luminance. This can be the case where a black image is present in the unit group UG in which the auxiliary light source 320 is disposed.

Since the auxiliary light source 320 outputs the minimum luminance of the luminance compensated area HBA, it can be turned off in the case where a black image is present. Therefore, in the second display area CA, the first unit pixel DP1 disposed in the unit group UG can have to cover the entire luminance of the unit group UG, and thus can be output at 400%.

However, since the first display area DA includes the first to fourth unit pixels DP1, DP2, DP3, and DP4, when outputting a white image, the first to fourth unit pixels DP1 to DP4 can each be output at 100% luminance, so that luminance differences can occur between pixels.

Therefore, in the boundary area BA, the luminance of the first unit pixel DP1 can gradually decrease toward the second display area CA, and can be matched to 100% luminance near the first display area DA. Conversely, the second to fourth unit pixels DP2, DP3, and DP4 can gradually increase their outputs from 0% luminance to reach 100% luminance near the first display area DA. A CA reference distance is a distance away from the CA. When the reference distance is 0, it means that it is disposed inside the CA, and as the reference distance increases, it can mean that it is farther away from the CA.

According to the embodiment, the first unit pixel DP1 having high luminance can be controlled so that the luminance gradually decreases in the boundary area BA, and the second to fourth unit pixels DP2 to DP4 can be controlled so that the luminance gradually increases, thereby improving the luminance difference between the second display area CA and the first display area DA.

Referring to FIG. 20, for example, in the second display area CA, the auxiliary light source 320 can be output at 50% and the luminance of the first unit pixel DP1 can be output at 250% to implement a specific image.

The auxiliary light source 320 outputs at the minimum luminance of the luminance compensated area HBA, and therefore can be output at 50% luminance in accordance with the minimum luminance. The first unit pixel DP1 can be output at 250% luminance to match the luminance of the unit area.

However, because the first display area DA includes the first to fourth unit pixels DP1, DP2, DP3, and DP4, a luminance difference can occur when a white image is displayed, as each pixel outputs at 100% luminance.

Therefore, in the boundary area BA, the luminance of the first unit pixel DP1 can gradually decrease from 250% toward the second display area CA and be matched to 100% luminance near the first display area DA, while the second to fourth unit pixels can gradually increase their outputs from the minimum luminance of 50% output by the auxiliary light source to be matched to 100% near the first display area DA.

Although embodiments of the present disclosure have been described above with reference to the accompanying drawings, those skilled in the art to which the present disclosure belongs will understand that the present disclosure can be implemented in other specific forms without changing its technical idea or essential features. Therefore it should be understood that the embodiments described above are illustrative in all aspects and do not limit the present disclosure.

### List of Reference Numbers

100: Display panel
110: Data driver
111: Luminance controller
130: Timing controller
300: Luminance control member
320: Auxiliary light source

What is claimed is:

1. A display device, comprising:
a display panel;
a data driver configured to apply a data signal to the display panel; and
a timing controller configured to apply the data signal to the data driver,
wherein the display panel includes:
a first display area in which a plurality of first pixels are disposed,
a second display area including a pixel area in which a plurality of second pixels are disposed and a plurality of light-transmission areas, and
a luminance control member configured to control a luminance of light emitted from the second display area.

2. The display device of claim 1, wherein the luminance control member is configured to emit light to the second display area to control the luminance of light emitted from the second display area.

3. The display device of claim 1, wherein the plurality of second pixels and the plurality of light-transmission areas of the second display area are divided into a plurality of unit groups, and
the luminance control member includes an auxiliary light source configured to control the luminance of light emitted from a luminance compensated area including one or more of the plurality of unit groups.

4. The display device of claim 3, wherein the auxiliary light source includes a first auxiliary light source configured to emit red light, a second auxiliary light source configured to emit green light, and a third auxiliary light source configured to emit blue light.

5. The display device of claim 4, wherein the first auxiliary light source is configured to emit red light of minimum luminance within the luminance compensated area,
the second auxiliary light source is configured to emit green light of minimum luminance within the luminance compensated area, and
the third auxiliary light source is configured to emit blue light of minimum luminance within the luminance compensated area.

6. The display device of claim 3, wherein the auxiliary light source is overlapped with the pixel area and a light-transmission area among the plurality of light-transmission areas.

7. The display device of claim 3, wherein the auxiliary light source is overlapped with a light-transmission area among the plurality of light-transmission areas, but is not overlapped with the pixel area.

8. The display device of claim 3, wherein the auxiliary light source is disposed at a lower portion of a light-emitting layer of a second pixel among the plurality of second pixels.

9. The display device of claim 3, wherein the luminance control member further includes a diffusion plate disposed on the auxiliary light source.

10. The display device of claim 3, further comprising a light reflection filter disposed between a substrate of the display panel and the luminance control member.

11. The display device of claim 10, wherein the light reflection filter is configured to transmit or reflect external incident light so as to be incident on an imaging unit, and is configured to reflect or transmit light emitted from the luminance control member so as to be emitted to an outside.

12. The display device of claim 3, wherein the timing controller includes:
a data receiver configured to receive frame-by-frame image data; and
an image analyzer configured to analyze the image data to extract a minimum luminance of the second display area.

13. The display device of claim 12, wherein the timing controller further includes:
a control signal generator configured to generate a control signal for controlling a luminance of the plurality of second pixels and the auxiliary light source according to the minimum luminance of the second display area; and
a data transmitter configured to transmit the control signal to the data driver and to a luminance controller for controlling the luminance control member.

14. The display device of claim 3, wherein the display panel further includes a boundary area disposed between the first display area and the second display area,
the first display area, the second display area, and the boundary area include unit pixels within a unit group of the same size, and
the second display area includes a first unit pixel within the unit group.

15. The display device of claim 14, wherein the first display area and the boundary area include first to fourth unit pixels within the unit group, and
the first to fourth unit pixels disposed in the boundary area are configured so that the luminance is continuously changed from the second display area toward the first display area.

16. The display device of claim 15, wherein the luminance of the first unit pixel of the boundary area is decreased from the second display area toward the first display area, and
the luminance of the second to fourth unit pixels of the boundary area is increased from the second display area toward the first display area.

17. The display device of claim 4, wherein sizes of first to third auxiliary light sources of the auxiliary light source are greater than a size of the second pixel.

18. The display device of claim 4, wherein the first to third auxiliary light sources of the auxiliary light source include organic light-emitting elements.

19. The display device of claim 4, wherein the first to third auxiliary light sources of the auxiliary light source include micro inorganic light-emitting elements.

20. The display device of claim 4, wherein the first to third auxiliary light sources of the auxiliary light source are disposed between the plurality of second pixels.
